(19) United States
(12) Patent Application Publication
(10) Pub. No.: US 2015/0357593 A1
(43) Pub. Date: Dec. 10, 2015

(54) ORGANIC ELECTROLUMINESCENT DISPLAY DEVICE

(71) Applicant: Japan Display Inc., Tokyo (JP)

(72) Inventors: Masakazu GUNJI, Tokyo (JP); Toshihiro SATO, Tokyo (JP)

(21) Appl. No.: 14/732,381

(22) Filed: Jun. 5, 2015

(30) Foreign Application Priority Data
Jun. 6, 2014 (JP) 2014-117668

(51) Int. Cl. H01L 51/50; H01L 51/52

(52) U.S. Cl. CPC H01L 51/5092; H01L 51/5206; H01L 51/5221; H01L 51/5088; H01L 51/5056; H01L 51/5012; H01L 51/5072; H01L 2251/562

(57) ABSTRACT

An organic EL display device includes an anode electrode made of a conductive material, a cathode electrode made of a conductive material, an anode-side electron injection layer that is an electron injection layer on the anode electrode and between the anode electrode and the cathode electrode, and an anode-side charge generation layer that is a charge generation layer on the anode-side electron injection layer.

### CROSS-REFERENCE TO RELATED APPLICATION

The present application claims priority from Japanese application JP2014-117668 filed on Jun. 6, 2014, the content of which is hereby incorporated by reference into this application.

### BACKGROUND OF THE INVENTION

1. Field of the Invention

The present invention relates to an organic electroluminescent (EL) display device.

2. Description of the Related Art

In recent years, image display devices including a self-luminous element called an organic light-emitting diode, hereinafter simply “organic EL display devices”, have been in practical use. Such an organic EL display device with a self-luminous element is excellent in visibility and response speed compared with liquid crystal display devices known in the art. Additionally, the organic EL display device eliminates the need for an auxiliary lighting device, such as a backlight, and thus can be made thinner.

JP 2006-049906 A discloses an organic light-emitting device that includes a cathode, an electron transport layer, an electroluminescent layer, a hole transport layer, an electron-accepting layer, and an anode in this order, and further includes an anode-capping layer between the electron-accepting layer and the anode.

For the organic EL display device, O2 plasma treatment is applied to its anode electrode, which is formed of indium tin oxide (ITO) or the like in an organic EL element in each pixel, to remove organic matter stacked on the anode electrode and lower the drive voltage of the organic EL element. The O2 plasma treatment, however, may cause decomposition of the materials for the circuit substrate depending on conditions and thus affect the ionization potential of the anode electrodes to result in unevenness in the hole-injecting properties of the anode electrodes. Other factors than this may also cause unevenness in the hole-injecting properties of the anode electrodes. The unevenness in the hole-injecting properties may reduce the device efficiency and increase the drive voltage, thus resulting in a shorter device life.

### SUMMARY OF THE INVENTION

In view of the above circumstances, it is an object of the present invention to provide an organic EL display device that has a higher device efficiency and a longer device life even when there is unevenness in the hole-injecting properties of its anode electrodes.

An organic EL display device according to an aspect of the present invention includes an anode electrode made of a conductive material, a cathode electrode made of a conductive material, an anode-side electron injection layer that is an electron injection layer on the anode electrode and between the anode electrode and the cathode electrode, and an anode-side charge generation layer that is a charge generation layer on the anode-side electron injection layer.

The organic EL display device according to the aspect may further include an anode-side hole injection layer that is a hole injection layer on the anode-side charge generation layer, an anode-side hole transport layer that is a hole transport layer on the anode-side hole injection layer, a light-emitting portion that is on the anode-side hole transport layer and includes at least one light-emitting layer made of an organic light-emitting material, a cathode-side electron transport layer that is an electron transport layer on the light-emitting portion, and a cathode-side electron injection layer that is an electron injection layer between the cathode-side electron transport layer and the cathode electrode.

In the organic EL display device according to the aspect, the light-emitting portion may include a cathode-side light-emitting layer made of an organic light-emitting material, an anode-side light-emitting layer that is made of an organic light-emitting material and is closer to the anode electrode than the cathode-side light-emitting layer, a tandem electron transport layer that is an electron transport layer on the anode-side light-emitting layer, a tandem electron injection layer that is an electron injection layer on the tandem electron transport layer, a tandem charge generation layer that is a charge generation layer on the tandem electron injection layer, a tandem hole injection layer that is a hole injection layer on the tandem charge generation layer, and a tandem hole transport layer that is a hole transport layer between the tandem hole injection layer and the cathode-side light-emitting layer.

### BRIEF DESCRIPTION OF THE DRAWINGS

FIG. 1 is a diagram schematically showing an organic EL display device according to an embodiment of the present invention;

FIG. 2 is a diagram showing a configuration of an organic EL panel seen in FIG. 1;

FIG. 3 is a diagram schematically showing a cross section of a sub-pixel in a thin film transistor (TFT) substrate taken along line III-III in FIG. 2;

FIG. 4 is a diagram schematically showing a stack structure of an organic layer of an organic EL element;

FIG. 5 is a diagram schematically showing a stack structure of an organic layer according to a comparative example of the present invention;

FIG. 6 is a graph showing measurements of changes in brightness against current supply time for the organic layer shown in FIG. 4 and the organic layer shown in FIG. 5;

FIG. 7 is a graph showing measurements of changes in the drive voltage of the organic EL element against current supply time for the organic layer shown in FIG. 4 and the organic layer shown in FIG. 5; and

FIG. 8 is a diagram schematically showing a stack structure of a tandem-structured organic layer according to a comparative example of the present embodiment.

### DETAILED DESCRIPTION OF THE INVENTION

Embodiments of the present invention are described below with reference to the accompanying drawings. The disclosure herein is merely an example, and appropriate modifications coming within the spirit of the present invention, which are easily conceived by those skilled in the art, are intended to be included within the scope of the invention as a matter of course. The accompanying drawings schematically illustrate widths, thicknesses, shapes, or other characteristics of each part for clarity of illustration, compared to actual configurations. However, such a schematic illustration is merely an example and not intended to limit the present invention. In the present specification and drawings, some elements identical or similar to those shown previously are denoted by the same reference signs as the previously shown elements, and thus repetitive detailed descriptions of them may be omitted as appropriate.

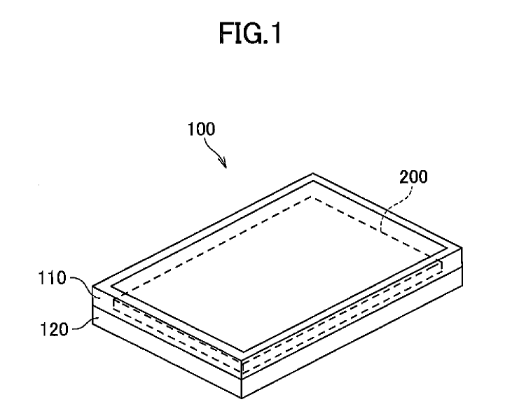

FIG. 1 schematically shows an organic EL display device 100 according to an embodiment of the present invention. As shown in the diagram, the organic EL display device 100 includes an upper frame 110, a lower frame 120, and an organic EL panel 200 fixed between the upper frame 110 and the lower frame 120.

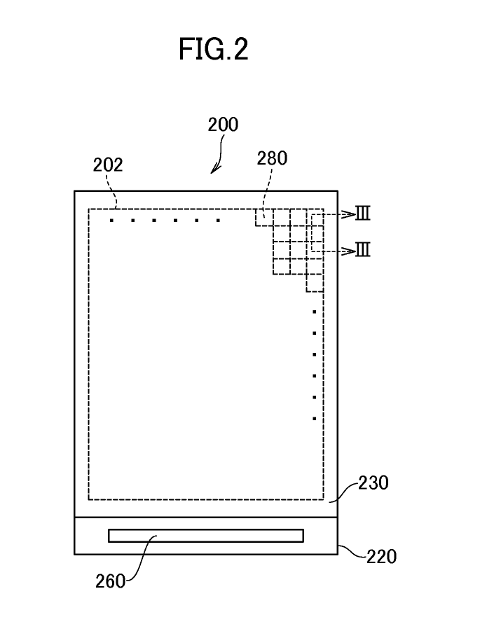

FIG. 2 shows a configuration of the organic EL panel 200 seen in FIG. 1. The organic EL panel 200 has a TFT substrate 220, a counter substrate 230, and a transparent resin (not shown) filled between these two substrates. The TFT substrate 220 has sub-pixels 280 arranged in a matrix in a display area 202. For example, a combination of three or four sub-pixels 280, which emit light in different wavelength ranges, constitutes a single pixel. On the TFT substrate 220, a driver integrated circuit (IC) 260 is disposed. The driver IC 260 applies a potential for conducting between the source and the drain of a pixel transistor arranged in each sub-pixel 280 to the corresponding scan line, and applies a voltage corresponding to a grayscale value of each sub-pixel 280 to the corresponding data line.

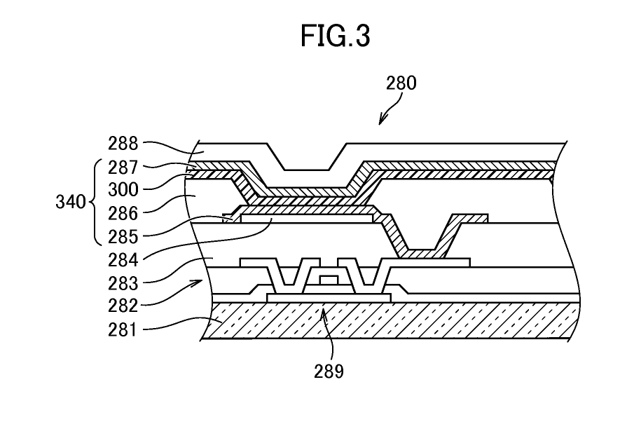

FIG. 3 is a diagram schematically showing a cross section of the sub-pixel 280 of the TFT substrate 220 taken along line III-III in FIG. 2. As shown in the diagram, the sub-pixel 280 of the TFT substrate 220 has a glass substrate 281, a TFT circuit layer 282, a planarization film 283, an anode electrode 285, an insulating bank 286, an organic layer 300, a reflective layer 284, a cathode electrode 287, and a sealing film 288. The glass substrate 281 is an insulating substrate. The TFT circuit layer 282, formed on the glass substrate 281, includes a circuit having a driver transistor 289 and the like. The planarization film 283, made of an insulating material, is formed on the TFT circuit layer 282. The anode electrode 285 is coupled to the circuit of the TFT circuit layer 282 through a through-hole in the planarization film 283. The insulating bank 286 covers the edge of the anode electrode 285 to insulate this anode electrode 285 from the different anode electrodes 285 in the adjacent sub-pixels 280. The organic layer 300 is formed on the anode electrode 285 and the insulating bank 286 to entirely cover the display area 202. The reflective layer 284 reflects light emitted by a light-emitting portion 320, described below, in the organic layer 300. The cathode electrode 287 is formed on the organic layer 300 to entirely cover the display area 202. The sealing film 288 keeps out air and water to prevent deterioration of the organic layer 300. The driver transistor 289 controls the brightness of the light emitted by the light-emitting portion 320 in the organic layer 300 in each sub-pixel 280. In this embodiment, the structure from the anode electrode 285 to the cathode electrode 287 is referred to as an organic EL element 340. FIG. 3 shows an example cross-section of the TFT substrate 220 used in a top-emitting organic EL display device. Alternatively, the TFT substrate 220 may be modified to adapt to a bottom-emitting organic EL display device or be modified to have another cross section. The transistors in the TFT circuit layer 282 may be made of amorphous silicon, low-temperature polysilicon, or other semiconductor materials. The organic layer 300 in this embodiment is formed to entirely cover the display area 202, whereas the organic layer 300 may be formed separately for each sub-pixel. In this case, the color of light emitted in each sub-pixel can be different.

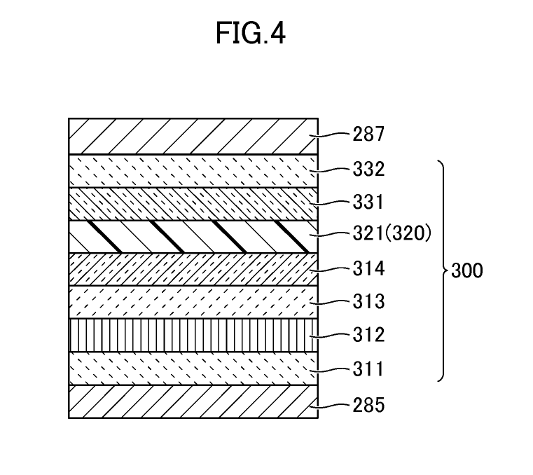

FIG. 4 is a diagram schematically showing a stack structure of the organic layer 300 of the organic EL element 340. As shown in the diagram, the organic layer 300, formed between the anode electrode 285 and the cathode electrode 287, includes an anode-side electron injection layer 311, which is an electron injection layer (EIL) formed on the anode electrode 285, an anode-side charge generation layer 312, which is a charge generation layer (CGL) formed on the anode-side electron injection layer 311, an anode-side hole injection layer 313, which is a hole injection layer (HIL) formed on the anode-side charge generation layer 312, an anode-side hole transport layer 314, which is a hole transport layer (HTL) formed on the anode-side hole injection layer 313, a light-emitting layer 321, which is the light-emitting portion 320 formed on the anode-side hole transport layer 314, a cathode-side electron transport layer 331, which is an electron transport layer (ETL) formed on the light-emitting layer 321, a cathode-side electron injection layer 332, which is an electron injection layer (EIL) formed between the cathode-side electron transport layer 331 and the cathode electrode 287, stacked in this order. Adjacent layers of these layers are directly in contact with each other.

The electron injection layer is preferably a layer formed from a mixture of a high-mobility material, such as biphasic calcium phosphate (BCP), Tris-(8-hydroxyquinoline) aluminum (Alq3), an oxadiazole (polybutadiene:PBD) based material, or a triazole-based material, and an alkali metal, such as Li, Mg, Ca, or Cs. The charge generation layer is preferably formed of an electron acceptor material, such as HAT-CN(6) (1,4,5,8,9,12-hexaazatriphenylene-hexacarbonitrile). The hole injection layer can be formed of, for example, any of HAT-CN(6), CuPc, and PEDOT:PSS. The hole transport layer can be formed of, for example, N,N′-Di-[(1-naphthyl)-N,N′-diphenyl]-1,1′-biphenyl)-4,4′-diamine (NPB).

The electron transport layer can be formed by co-deposition of Alq3 and 8-hydroxy-quinolinato-lithium (Liq). Here, for example, Li may be substituted for Liq. The materials used for each of the above layers are not limited to the materials shown here, and any material that those skilled in the art use for each layer may be used.

In this embodiment, the anode-side electron injection layer 311 is formed between the anode electrode 285 and the anode-side charge generation layer 312. This structure makes hole injection from the anode electrode 285 to the anode-side electron injection layer 311 less likely to occur. In addition, the anode-side charge generation layer 312 generates holes for light emission and provides them to the anode-side hole transport layer 314. Thus, the organic EL element 340 can be driven unaffected by the hole-injecting properties of the anode electrode 285. Electrons generated in the anode-side charge generation layer 312 move to the anode electrode 285 through the anode-side electron injection layer 311. Thus, the amount of holes can be controlled regardless of the surface treatment condition of the anode electrode 285, and the device efficiency and the life of the organic EL element 340 can be increased. The materials for the anode-side electron injection layer 311 and the cathode-side electron injection layer 332 may be the same or different. The structure, above the anode-side electron injection layer 311, from the anode-side hole injection layer 313 to the cathode-side electron injection layer 332 is not particularly limited, and may be stacked differently only if the anode-side electron injection layer 311, which makes the hole injection less likely to occur, is formed on the anode electrode 285 and a charge generation layer, which generates electric charges, is formed on the anode-side electron injection layer 311.

Such a structure enables the material for the anode electrode 285 to be a metal that has low hole-injecting properties, that is, a low work function. Whereas the work function of the ITO commonly used for the anode electrode 285 is about 4.26 eV, it is modified to be about 5.0 to 5.5 eV for practical use, for example, by O2 plasma treatment. However, if the hole-injecting properties of the anode electrode 285 can be lowered, a low work function metal, such as Al with a work function of 4.28 eV or Ag with a work function of 4.26 eV, can be used. Use of such a metal has a cost advantage over use of the ITO and can also improve the flatness of the anode electrode 285 to reduce leakage. Moreover, its non-transparency can eliminate the need for a fine adjustment of the thickness of the anode electrode 285 when optical interference is used.

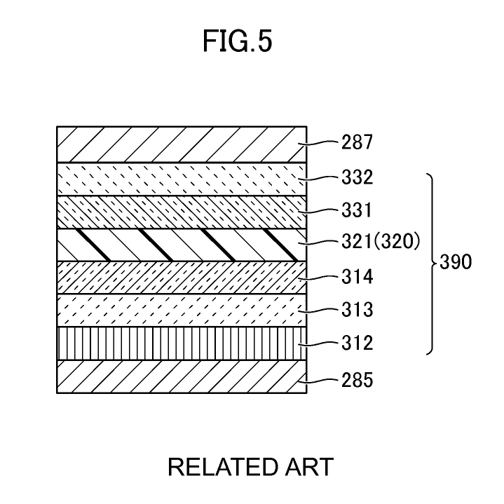

FIG. 5 is a diagram schematically showing a stack structure of an organic layer 390 according to a comparative example of the present invention. The organic layer 390 differs from the organic layer 300 shown in FIG. 4 in that the anode-side charge generation layer 312 is formed directly on the anode electrode 285 without the anode-side electron injection layer 311. The other layers are the same as those shown in FIG. 4, and thus are not described here. In this case, the hole-injecting properties of the anode electrode 285 affect the device efficiency.

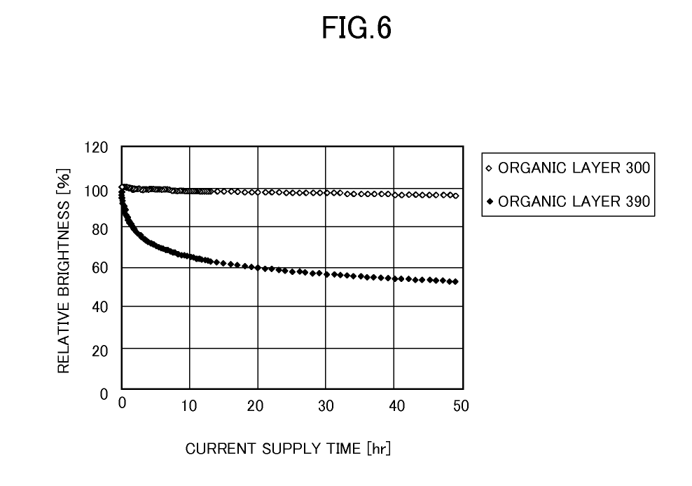

FIG. 6 is a graph showing measurements of changes in brightness against current supply time for the organic layer 300 shown in FIG. 4 and the organic layer 390 shown in FIG. 5. As shown in the graph, the brightness of the organic layer 300 with the anode-side electron injection layer 311 remains almost the same as the initial level even 50 hours after the start of current supply, whereas the brightness of the organic layer 390 without the anode-side electron injection layer 311 drops to half of the initial level. Thus, such structure as the organic layer 300 shown in FIG. 4 can prevent deterioration of the organic EL element 340 and extend the life.

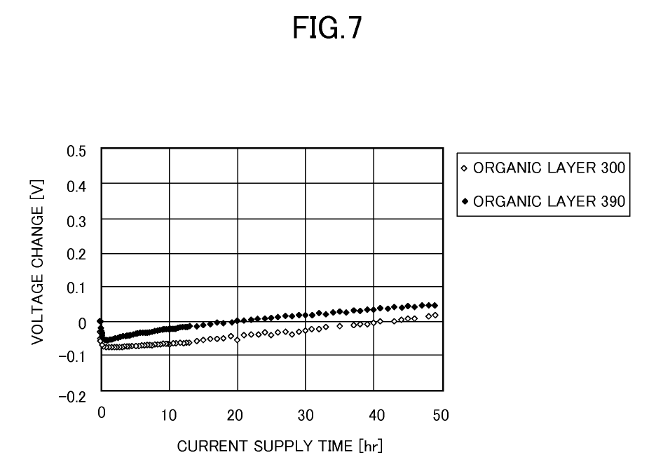

FIG. 7 is a graph showing measurements of changes in the drive voltage of the organic EL element 340 against current supply time for the organic layer 300 shown in FIG. 4 and the organic layer 390 shown in FIG. 5. As shown in the graph, the drive voltage of the organic layer 300 with the anode-side electron injection layer 311 stays almost unchanged without increasing power consumption even 50 hours after the start of current supply, compared with that of the organic layer 390 without the anode-side electron injection layer 311.

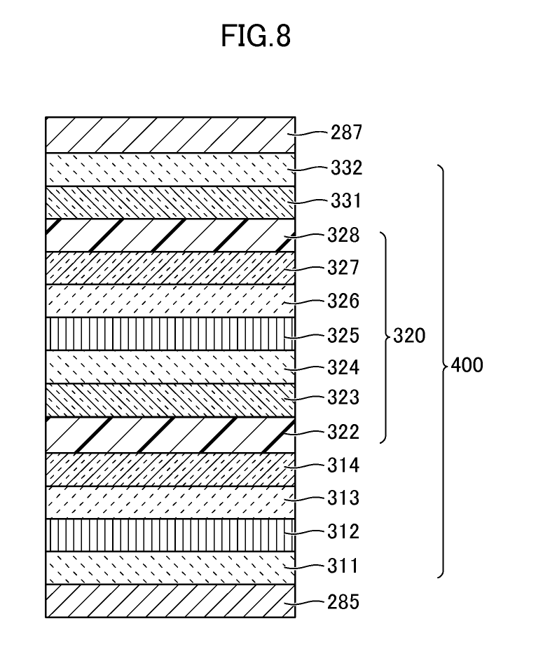

FIG. 8 is a diagram schematically showing a stack structure of a tandem-structured organic layer 400 according to a comparative example of the above embodiment. The organic layer 400 differs from the organic layer 300 shown in FIG. 4 in that the light-emitting portion 320 has what is called a tandem structure, in which two light-emitting layers, an anode-side light-emitting layer 322 and a cathode-side light-emitting layer 328, are arranged apart from each other.

The light-emitting portion 320 includes a tandem electron transport layer 323, which is an electron transport layer formed on the anode-side light-emitting layer 322, a tandem electron injection layer 324, which is an electron injection layer formed on the tandem electron transport layer 323, a tandem charge generation layer 325, which is a charge generation layer formed on the tandem electron injection layer 324, a tandem hole injection layer 326, which is a hole injection layer formed on the tandem charge generation layer 325, and a tandem hole transport layer 327, which is a hole transport layer formed between the tandem hole injection layer 326 and the cathode-side light-emitting layer 328, stacked in this order.

Even the organic layer 400, which includes the light-emitting portion 320 having such a tandem structure, can produce the same effects as the above embodiment because the organic layer 400 includes the anode-side electron injection layer 311 between the anode electrode 285 and the anode-side charge generation layer 312. The tandem stack structure between the two light-emitting layers is not limited to this structure, and may have another stack structure. Whereas the tandem structure includes two light-emitting layers, it may include three or more light-emitting layers.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic EL display device comprising:
an anode electrode made of a conductive material;
a cathode electrode made of a conductive material;
an anode-side electron injection layer, the anode-side electron injection layer being an electron injection layer on the anode electrode and between the anode electrode and the cathode electrode; and
an anode-side charge generation layer, the anode-side charge generation layer being a charge generation layer on the anode-side electron injection layer.

2. The organic EL display device according to claim 1, wherein
the anode electrode and the anode-side electron injection layer are directly in contact with each other.

3. The organic EL display device according to claim 2, wherein
the anode-side electron injection layer and the anode-side charge generation layer are directly in contact with each other.

4. The organic EL display device according to claim 1, wherein
the anode-side electron injection layer prevents hole injection from the anode electrode.

5. The organic EL display device according to claim 1, wherein
electrons generated in the anode-side charge generation layer moves to the anode electrode through the anode-side electron injection layer.

6. The organic EL display device according to claim 1, further comprises:
an anode-side hole injection layer, the anode-side hole injection layer being a hole injection layer on the anode-side charge generation layer;
an anode-side hole transport layer, the anode-side hole transport layer being a hole transport layer on the anode-side hole injection layer;
a light-emitting portion on the anode-side hole transport layer, the light-emitting portion including at least one light-emitting layer made of an organic light-emitting material;
a cathode-side electron transport layer, the cathode-side electron transport layer being an electron transport layer on the light-emitting portion; and
a cathode-side electron injection layer, the cathode-side electron injection layer being an electron injection layer between the cathode-side electron transport layer and the cathode electrode.

7. The organic EL display device according to claim 6, wherein
the anode-side charge generation layer and the anode-side hole injection layer are directly in contact with each other.

8. The organic EL display device according to claim 6, wherein
the anode-side charge generation layer generates holes for light emission in the at least one light-emitting layer and provides the holes to the anode-side hole transport layer.

9. The organic EL display device according to claim 6, wherein
the light-emitting portion includes:
a cathode-side light-emitting layer made of an organic light-emitting material;
an anode-side light-emitting layer made of an organic light-emitting material, the anode-side light-emitting layer being closer to the anode electrode than the cathode-side light-emitting layer;
a tandem electron transport layer, the tandem electron transport layer being an electron transport layer on the anode-side light-emitting layer;
a tandem electron injection layer, the tandem electron injection layer being an electron injection layer on the tandem electron transport layer;
a tandem charge generation layer, the tandem charge generation layer being a charge generation layer on the tandem electron injection layer;
a tandem hole injection layer, the tandem hole injection layer being a hole injection layer on the tandem charge generation layer; and
a tandem hole transport layer, the tandem hole transport layer being a hole transport layer between the tandem hole injection layer and the cathode-side light-emitting layer.
